(19) United States
(12) Patent Application Publication
(10) Pub. No.: US 2008/0290482 A1
(43) Pub. Date: Nov. 27, 2008

(54) METHOD OF PACKAGING INTEGRATED CIRCUITS

(75) Inventors: Jaime A. Bayan, Palo Alto, CA (US); Nghia Tu, San Jose, CA (US); Will K. Wong, Daly City, CA (US)

Correspondence Address: Beyer Law Group LLP, P.O. BOX 1687, Cupertino, CA, 95015-1687, US

(73) Assignee: NATIONAL SEMICONDUCTOR CORPORATION, Santa Clara, CA (US)

(21) Appl. No.: 11/858,032

(22) Filed: Sep. 19, 2007

Related U.S. Application Data
(63) Continuation-in-part of application No. 11/754,139, filed on May 25, 2007.

(51) Int. Cl. H01L 23/495; H01L 21/60; H01L 23/28

(52) U.S. Cl. 257/670; 257/723; 438/112; 438/114; 257/E23.031; 257/E23.116; 257/E21.506

(57) ABSTRACT

A method of packaging integrated circuit dice into exposed die packages is described. The method includes depositing a metallic layer onto the back surface of an integrated circuit wafer such that it covers the back surface. The method additionally includes applying a protective layer over the metallic layer such that the protective layer covers the metallic layer. The method further includes singulating the wafer to produce individual dice. Each die may then be electrically connected to a lead frame. The die and portions of the lead frame may then be encapsulated with a molding compound. The protective layer inhibits the molding compound from contacting the metallic layer on the back surface of the die. The protective layer is then removed from the metallic layer. As a result, an individual IC package is produced that includes a die having a metallic layer exposed on the back surface of the die.

### CROSS REFERENCE TO RELATED APPLICATIONS

This application is a Continuation in Part of U.S. patent application Ser. No. 11/754,139 filed on May 25, 2007 and entitled “METHOD OF PACKAGING INTEGRATED CIRCUITS,” which is incorporated herein by reference in its entirety.

### TECHNICAL FIELD

The present invention relates generally to the packaging of integrated circuits (ICs). More particularly, an improved method is described for preparing and packaging IC dice into exposed die packages.

### BACKGROUND OF THE INVENTION

There are a number of conventional processes for packaging integrated circuit (IC) dice. By way of example, many IC packages utilize a metallic lead frame. The die may be electrically connected to the lead frame by means of bonding wires or solder bumps that have been preformed on the active surface of the die. In general, the die and portions of the lead frame are encapsulated with a molding compound to protect the delicate electrical components on the active side of the die. In some applications, it is desirable to leave the back surface (opposite the active surface) of the die exposed; that is, not to encapsulate the back surface of the die with molding compound. By way of example, it may be desirable to leave the back surface of the die exposed in order to increase heat transfer out of the die. This is especially relevant for packages used in power applications. In such exposed die packages, the back surface of the die may be pre-coated with a thin metallic layer. In some applications, the metallic layer may be soldered directly to a printed circuit board (PCB) in order to further enhance the heat transfer out of the die.

It is therefore desirable that the molding compound not intrude over the metallic layer during the encapsulation process, a phenomenon known as mold flash or bleed, as the molding compound may inhibit heat transfer out of the die as well as inhibiting soldering between the metallic layer on the back surface of the die and the PCB. While methods exist for removing molding compound that has intruded over the metallic layer, it is desirable to develop more efficient methods for producing exposed die packages such that the metallic layer on the back surface of the die is exposed and uncovered by molding compound.

### SUMMARY OF THE INVENTION

In one embodiment, a method of packaging integrated circuit dice into exposed die packages is described. The method includes depositing a metallic layer onto a back surface of an integrated circuit wafer. The wafer includes a large number of integrated circuit dice. Each die has an active surface and a back surface. Each active surface includes a plurality of bond pads. Each back surface is opposite the active surface. The back surfaces of the dice cooperate to form the back surface of the wafer. The metallic layer is deposited such that the metallic layer covers the back surface of the wafer. The method also includes applying a protective layer over the metallic layer such that the protective layer covers the metallic layer. The method also includes singulating the wafer into individual integrated circuit dice after applying the protective layer over the metallic layer. The method also includes encapsulating one of the singulated dice with a molding compound. The protective layer on the die prevents the molding compound from contacting the metallic layer on the die during the encapsulation process. The method further includes removing the protective layer from the metallic layer on the encapsulated die thereby providing an individual IC package that includes a die having a metallic layer that is entirely exposed on the die's back surface.

In another embodiment, a method of packaging integrated circuit dice into exposed die packages is described. The method includes providing an integrated circuit die. The die includes a metallic layer that is deposited onto the back surface of the die such that the metallic layer covers the back surface of the die. The die additionally includes a protective layer applied over the metallic layer such that the protective layer covers the metallic layer. The method also includes encapsulating the die with a molding compound. The protective layer on the die prevents the molding compound from contacting the metallic layer on the die during the encapsulation process. The method further includes removing the protective layer from the metallic layer on the encapsulated die thereby providing an individual IC package that includes a die having a metallic layer that is entirely exposed on the die's back surface.

In another embodiment, a method of packaging integrated circuit dice into exposed die packages is described. The method includes depositing a metallic layer onto a back surface of an integrated circuit wafer. The wafer includes a large number of integrated circuit dice. Each die has an active surface and a back surface. Each active surface includes a plurality of bond pads. Each back surface is opposite the active surface. The back surfaces of the dice cooperate to form the back surface of the wafer. The metallic layer is deposited such that the metallic layer covers the back surface of the wafer. The method further includes applying a protective layer of high temperature paint over the metallic layer such that the protective layer of high temperature paint covers the metallic layer.

In another embodiment, a method of packaging integrated circuit dice into exposed die packages is described. The method includes depositing a metallic layer onto a back surface of an integrated circuit wafer. The wafer includes a large number of integrated circuit dice. Each die has an active surface and a back surface. Each active surface includes a plurality of bond pads. Each back surface is opposite the active surface. The back surfaces of the dice cooperate to form the back surface of the wafer. The metallic layer is deposited such that the metallic layer covers the back surface of the wafer. The method further includes applying a protective layer of a water-based emulsion over the metallic layer such that the protective layer of the water-based emulsion covers the metallic layer.

In another embodiment, an arrangement is described that includes a wafer having a multiplicity of integrated circuit dice. Each die has an active surface and a back surface. Each active surface includes a plurality of bond pads. Each back surface is opposite the active surface. The back surfaces of the dice cooperate to form the back surface of the wafer. The arrangement also includes a metallic layer deposited onto the back surface of the wafer such that the metallic layer covers the back surface of the wafer. The arrangement further includes a protective layer deposited onto the metallic layer such that the protective layer covers the metallic layer.

In still another embodiment, an arrangement is described that includes a lead frame panel. The lead frame panel includes at least one two-dimensional array of device areas. Each adjacent device area is connected with associated tie bars. Each device area is suitable to receive an associated die. The arrangement further includes a plurality of dice. Each die is electrically connected to an associated devices area of the lead frame panel. Each die includes a metallic layer that is deposited onto the back surface of the die such that the metallic layer covers the back surface of the die. Each die additionally includes a protective layer applied over the metallic layer such that the protective layer covers the metallic layer.

### BRIEF DESCRIPTION OF THE DRAWINGS

For a better understanding of the invention, reference should be made to the following detailed description taken in conjunction with the accompanying drawings, in which:

FIG. 1 is a flow chart illustrating a process for preparing and packaging IC dice in accordance with an embodiment of the present invention;

FIGS. 2A-2B illustrate diagrammatic side views of a wafer and dice, respectively, having a protective layer formed on a back side thereof in accordance with an embodiment of the present invention;

FIGS. 3A-C illustrate diagrammatic top views of a lead frame panel suitable for use in packaging dice in accordance with an embodiment of the present invention;

FIGS. 4A-4C illustrate various package configurations in accordance with embodiments of the present invention.

Like reference numerals refer to corresponding parts throughout the drawings.

### DETAILED DESCRIPTION OF EXAMPLE EMBODIMENTS

The present invention relates generally to the packaging of integrated circuits (ICs). More particularly, an improved method is described for preparing and packaging IC dice into exposed die packages.

In the following description, numerous specific details are set forth to provide a thorough understanding of the present invention. It will be apparent, however, to one skilled in the art that the present invention may be practiced without some or all of these specific details. In other instances, well known process steps have not been described in detail in order to avoid unnecessary obscuring of the present invention.

In an exposed die package, the back surface of the die is left unencapsulated by molding compound used to encapsulate other portions of the die. Hence, the back surface of the die is left exposed to its surrounding environment. The back surface of the die used in an exposed die package may include a metallic layer deposited onto the back surface of the die prior to encapsulation. During encapsulation of the die, liquid molding compound at high temperature and pressure is generally injected into a mold cavity that encloses the die. The pressure is often high enough that the molding compound may intrude between the mold cavity and the back surface of the die (or more specifically any material layer deposited onto the back surface of the die) in contact with the mold cavity. This intrusion of molding compound is known as mold flash or mold bleed. In conventional packaging methods, this mold flash may inhibit or prevent mechanical and/or electrical connection between the metallic layer on the back surface of the die in an exposed die package and a substrate such as a PCB. At the very least, mold flash adversely affects the performance of the die by inhibiting heat transfer out of the exposed die package. Increasing heat transfer out of the die is particularly critical in power packages. As such, many power packages are exposed die packages. Examples of exposed die power packages include, by way of example, the SOT23 and SC70 power packages.

To overcome the problems associated with the intrusion of molding compound, current methods employ physical or chemical deflashing processes. By way of example, physical deflashing methods may include laser deflashing or even grinding/sanding to remove mold flash accumulated on the back surface of the die. Unfortunately, these processes may be damaging to the metallic layer and/or die. More particularly, as a result of the minute thickness of the metallic layer on the back surface of the die (the metallic layer is often sputtered onto the back surface of the die), the metallic layer may be easily damaged or even removed by physical deflashing. Additionally, laser deflashing may etch the molding compound around the die as well as contaminate the die with ions that may adversely affect the performance of the active circuits in the die. Chemical deflashing, too, suffers from drawbacks. By way of example, the chemicals used for chemical deflashing may also attack and remove the molding compound. The problems associated with physical and chemical deflashing are avoided by the methods of the present invention.

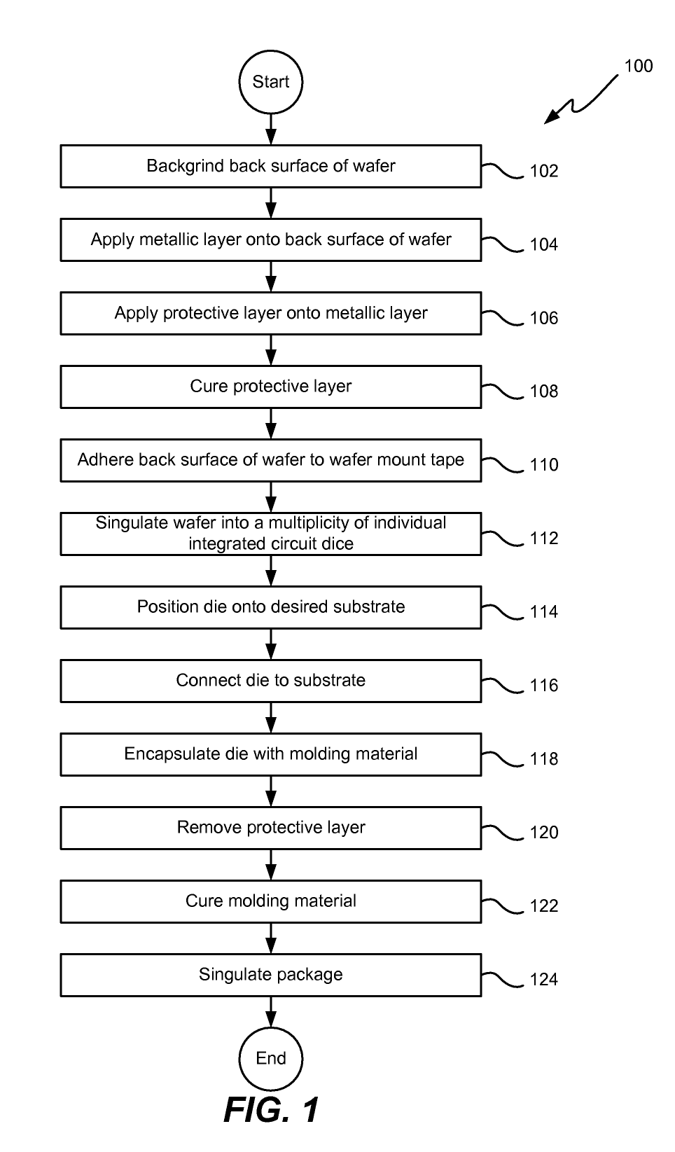

The following description focuses on the preparing and packaging of IC dice into exposed die packages. Various embodiments of the present invention will be described with reference to FIGS. 1-4. Aspects of the present invention provide a method for packaging IC dice such that an exposed metallic layer deposited onto the back surface of the die remains uncovered by molding compound used to encapsulate other portions of the die. More particularly, a method is described for applying a thin film of readily removable material over a metallic layer that has previously been deposited onto the back surface of a die. The thin film serves as a temporary protective layer that may serve a number of purposes. By way of example and not by way of limitation, during encapsulation while inside a molding cavity, the protective layer resists molding compound intrusion over the back surface metallic layer. Secondly, if, during encapsulation of the die, molding compound does intrude over the back surface, the protective layer prevents molding compound from contacting and adhering to the back surface metallic layer. Additionally, the protective layer may prevent chipping and other damage to dice during encapsulation or singulation of the dice from a wafer.

After encapsulation, the protective layer is removed thereby leaving the metallic layer exposed and uncovered by molding compound. Additionally, it should be appreciated that the methods described allow for complete inline integration with current packaging processes and readily available equipment. Furthermore, the described embodiments are compatible with virtually any molding system. This is in contrast to other methods that require specialized molding systems to prevent molding compound from covering the metallic layer on the back surface of the die. Additionally, the present methods may be practiced on both solder-bumped dice as well as on dice that are electrically connected to desired substrates via bonding wires.

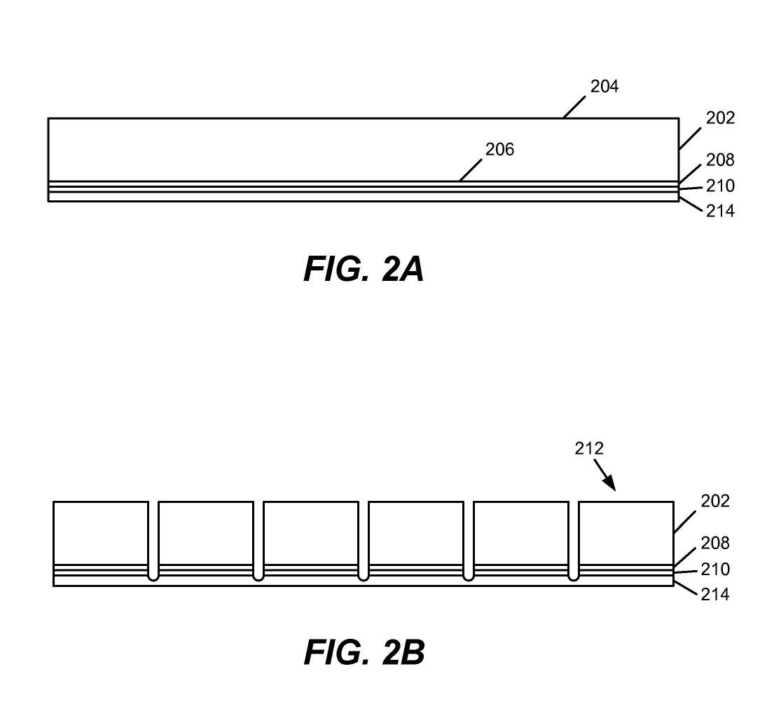

Referring initially to FIG. 1, and further in view of FIG. 2, a process 100 of preparing and packaging IC dice in accordance with particular embodiments of the present invention will be described. Initially, a semiconductor wafer 202 that includes a large number of dice is fabricated. By way of example, the wafer will typically have several hundred to several thousand dice formed thereon. As is well known in the art, most wafers and dice are formed of silicon (Si), although any other appropriate semiconductor material can also be used.

In one embodiment, the active surface 204 of the wafer is solder bumped. The solder bumps may be formed directly on I/O pads on the active surfaces of the dice or on other bond pads that have been redistributed from the I/O pads using conventional redistribution techniques. Additionally, underbump metallizations (UBMs) may be formed on the bond pads of the die prior to solder bumping. Generally, the solder bumps are intended to be mounted and attached directly to contact pads of a substrate, such as a lead frame or printed circuit board (PCB). In other embodiments in which the dice are to be electrically connected to desired substrates with bonding wires, the wafer is not solder bumped.

If it is desirable to thin the wafer 202, the back surface 206 of the wafer may be subjected to a backgrinding operation 102. Backgrinding allows the wafer to be brought into conformance with a desired thickness. Backgrinding may be accomplished by any of a number of methods known in the art. It should be appreciated that backgrinding is an entirely optional operation as the wafer may be in conformance to a desired thickness without backgrinding.

After the wafer 202 has been background, a thin metallic layer may be applied to the back surface 206 of the wafer at 104. The thin metallic layer 208 may be formed from any suitable metal or metallic alloy. By way of example, the thin metallic layer 208 may be an alloy of titanium, nickel and silver. The thin metallic layer 208 may be applied to the back surface 206 of the wafer 202 with any suitable means. By way of example, the metallic layer 208 may be sputtered onto the back surface 206 of the wafer. The metallic layer 208 may serve many purposes. By way of example, after singulation of the wafer into individual IC dice, the metallic layer 208 may serve as a heat transfer medium for transferring thermal energy out of the die. In some embodiments, the back surface 206 of the die is soldered directly to a desired substrate, such as a PCB, to provide for enhanced heat dissipation out of the die. Since solder does not adhere well to Si, the metallic layer serves as an intermediary between the solder and the Si. In other embodiments, such as in analog applications, it is desirable to electrically connect the back surface of the die to a PCB to allow control over the electrical potential of the back region of the die. In still other embodiments, it may be desirable to solder a heat sink to the back surface of the die to increase heat dissipation out of the die.

After application of the metallic layer 208, a protective layer 210 is applied onto the metallic layer at 106. The protective layer 210 may be formed from any suitable material that is readily removable from the metallic layer 208, that won't damage the metallic layer or die (e.g., corrode the metallic layer or contaminate the die with ions), and that is able to withstand the high temperatures and pressures associated with molding, reflow and/or other packaging processes. By way of example, molding temperatures may reach or exceed 175° C. while reflow temperatures may reach or exceed 260° C.

In one example embodiment, the protective layer 210 is formed from one of a number of conventional solder mask materials. As is well known in the art, solder masks are generally applied around electrical components, such as on the active surface of a die or PCB, in order to prevent solder bridging between electrical components as well as to provide environmental protection to the electrical components and other regions on the active surface of the die. The use of solder mask materials is advantageous in this regard as solder masking is already a part of many packaging processes and therefore, appropriate solder masking equipment is fairly widely distributed and readily available. Thus, no extra equipment is generally needed to apply the protective layer of solder mask 210 onto the metallic layer 208.

Conventional solder mask materials generally include, by way of example, screen printable epoxy inks and liquid photoimageable solder masks (LPSMs), among many others. Additionally, LPSMs can be further subdivided into liquid photoimageable inks and dry film solder masks (DFSMs). Other solder mask materials include photosensitive-benzocyclobutene (photo-BCB) and various other photopolymers. Generally, the method of application will largely depend on the material comprising the protective layer 210. By way of example, materials such as BCB may be applied using a spin coating process while various epoxies may be applied using screen-printing techniques. In some embodiments, it is necessary or desirable to cure the protective layer 210 at 108 prior to the encapsulation process. Depending upon its material composition, the protective layer 210 may be cured thermally, such as in an oven, through exposure with radiation, such as ultraviolet (UV) radiation, or by any other suitable means.

The protective layer 210 of solder mask may be applied in one or more layers to achieve the desired thickness. By way of example, the total thickness of the protective layer 210 of solder mask after curing may be in the range of approximately 50 to 100 μm, although other thicknesses, both thinner and thicker, may be suitable as well. If the protective layer 210 is applied in two or more layers, it may be desirable to allow previously applied layers to cure before application of additional layers. The application of multiple layers may also produce a protective layer 210 having a more consistent thickness across the wafer 202.

In another example embodiment, the protective layer 210 is formed from a high-temperature paint. More specifically, the paint material is chosen such that the protective layer 210 of paint won't crack, peal off, liquefy or vaporize during encapsulation and/or reflow. The paint material is additionally chosen such that the protective layer 210 of paint both adheres well to the metallic layer 208 and is readily removable from the metallic layer. By way of example, the paint may be a high-temperature rated enamel paint. The paint is also preferably a semiconductor grade paint; that is, a paint having fewer particulates, that is suitable for use in a clean room and that is not corrosive or otherwise damaging to either lead frame components or IC dice.

The paint may be applied to the back surface 206 of the wafer 202 using any suitable means. By way of example, the protective layer 210 of paint may be sprayed on or applied with a roller such as a rubber roller. In another particular embodiment, the paint is applied using a screen printing technique. It is desirable that the protective layer 210 be uniform in thickness across the wafer 202. As such, screen printing may be preferable as screen printing provides precise control over the thickness of the protective layer 210 across the wafer 202. The paint is preferably allowed to cure at 108 prior to the encapsulation process. While the paint may cure at room temperature, the curing process may be accelerated by placing the wafer 202 in an oven. By way of example, the temperature in the oven may be in the range of approximately 100-150° C. although a wide range of temperatures may be suitable.

The protective layer 210 of paint may also be applied in one or more layers to achieve the desired thickness. By way of example, the total thickness of the protective layer 210 of paint after curing may be in the range of approximately 50 to 100 μm, although other thicknesses, both thinner and thicker, may be suitable as well. Again, if the protective layer 210 of paint is applied in two or more layers, it may be desirable to allow previously applied layers to cure before application of additional layers.

In another example embodiment, the protective layer 210 may be formed from an emulsion. In one embodiment, the emulsion used to form the protective layer 210 is a water-based emulsion. Certain water-based emulsions are already generally used in packaging processes. By way of example, particular water-based emulsions may be used to soften molding material and are hence often used as molding compound release agents to clean molding cavities after encapsulation. Thus, in one preferred embodiment, an industry standard water-based emulsion designed for use as a mold release agent is used to form the protective layer 210. By way of example, one example of such a water-based emulsion mold release agent is RC7017A manufactured by Huron Technologies Inc.

The protective layer 210 of emulsion material may be applied to the back surface 206 of the wafer 202 using any suitable means. By way of example, the protective layer 210 of emulsion material may be sprayed on, brushed on with a brush, or applied using screen printing, spin coating or other suitable techniques for applying uniform protective layers. Again, as described above, it is generally desirable for the protective layer 210 to be uniform in thickness across the wafer 202. The protective layer 210 of emulsion is allowed to cure (dry) at 108 after application. Under ambient conditions, the emulsion may dry in roughly 10 minutes. It has been observed that the surface tension of particular emulsion materials cause the protective layer 210 to shrink when drying. More specifically, the protective layer 210 of emulsion may contract in both height and diameter after drying thus leaving the outermost edges of the wafer 202 uncovered by the protective layer. However, the outermost edges are typically not used to produce IC dice, so this shrinking is not a concern at the wafer level. As such, the protective layer 210 of emulsion is preferably applied at the wafer level as opposed to the die level, since it is the die edges that are most susceptible to molding compound intrusion.

As described with reference to the solder mask and high-temperature paint, the protective layer 210 of emulsion may be applied in one or more layers to achieve the desired thickness. By way of example, the total thickness of the protective layer 210 of emulsion material after drying may be in the range of approximately 50 to 100 μm, although other thicknesses, both thinner and thicker, may be suitable as well. As described above, if the protective layer 210 of emulsion material is applied in two or more layers, it may be desirable to allow previously applied layers to dry before application of additional layers.

Next, at 110, the back surface 206 of the wafer may be adhered to a wafer mount tape 214. The wafer 202 is then singulated at 112 into a large number of individual IC dice 212. Singulation may be accomplished through any of a number of suitable manners including sawing, gang cutting (sawing) or laser cutting. The singulation proceeds fully through the wafer 202, metallic layer 208 and protective layer 210 thereby completely separating the dice 212 from one another. However, in various embodiments, for ease of handling, the singulation does not proceed fully through the mount tape 214.

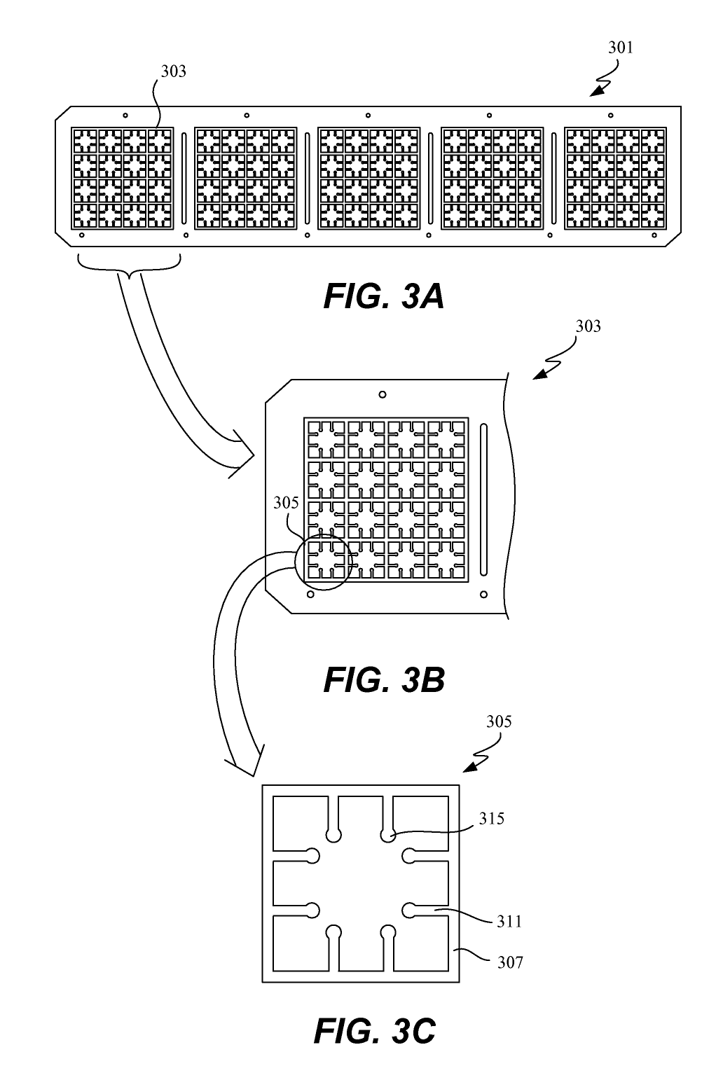

An individual die 212 may then be removed from the tape 214 and positioned onto a suitable substrate at 114. In one preferred embodiment, the substrate is a lead frame panel. With respect to FIGS. 3A-C, an exemplary lead frame panel 301 suitable for use in packaging integrated circuits according to various embodiments of the present invention will be described. FIG. 3A illustrates a diagrammatic top view of a lead frame panel 301 arranged in the form of a strip. The lead frame panel 301 can be configured as a metallic structure with a number of two-dimensional arrays 303 of device areas. As illustrated in the successively more detailed FIGS. 3B-C, each two-dimensional array 303 includes a plurality of device areas 305, each configured for use in a single IC package, and each connected by fine tie bars 307.

Each device area 305 may include a number of leads 311, each supported at one end by the tie bars 307. In the illustrated embodiment, the leads 311 include conductive die contacts 315 on the top surface of the lead frame at the proximal end of the lead. The leads 311 additionally include package contacts on the bottom surface of the lead frame at the distal ends of the leads. The leads 311 may be etched, half-etched, or otherwise thinned relative to the package contacts, so as to provide electrical connection to the contacts without leaving exposed conductive areas on the bottom surface of the lead frame panel 301. Additionally, it may also be desirable to etch or otherwise thin the top surface of the lead frame as well.

It will be appreciated by those skilled in the art that, although a specific lead-frame panel 301 has been described and illustrated, the described methods may be applied in packaging dice utilizing an extremely wide variety of other lead frame panel or strip configurations as well as other substrates. Thus, although the following description of particular embodiments describes the packaging of dice utilizing lead frame technology, those of skill in the art will understand that embodiments of the present invention may also be practiced using other substrates. Additionally, although described with references to a top and bottom surface of the lead frame panel 301, it should be appreciated that this context is intended solely for use in describing the structure and in no way defines or limits the orientation of the lead frame for subsequent attachment to a PCB or other substrate.

When placing solder-bumped dice 212 onto the lead frame 301, the solder bumps may be directly positioned onto contacts 315 located on the leads 311 of the lead frame. In embodiments such as these in which the active surface of each die 212 includes a plurality of solder bumps, the die is electrically and physically connected to the lead frame 301 by means of reflowing the solder bumps at 116 such that solder joints are formed between the bonds pads on the active surface of the die and the contacts 315 of the lead frame.

In other embodiments, dice 212 not having solder bumps may be positioned onto or within a leadframe at 114. In one embodiment, each die 212 may be positioned within a die attach area of a lead frame device area 305 that may or may not include a die attach pad. At 116, bond pads on the active surface of the dice 212 are electrically connected to contacts 315 located on the leads 311 of the lead frame with bonding wires.

At 118 portions of the dice 212 and lead frame 301 are encapsulated with a conventional molding compound 420. The molding compound is generally a non-conductive plastic or resin having a low coefficient of thermal expansion. In a preferred embodiment, an entire populated lead frame strip, such as lead frame panel 301, is placed in the mold such that the entire die-populated lead frame panel may be encapsulated substantially simultaneously. It should be appreciated that a lesser number of dice may also be encapsulated at any one time.

It should additionally be appreciated that virtually any molding system may be used to encapsulate the attached dice 212 and lead frame panel. By way of example, a film assisted molding (FAM) system may be used to encapsulate the attached dice. In such a system, a vacuum is used to draw a film or tape to the inner surfaces of the molding cavity. By way of example, the film used within the mold cavity may be a thermoplastic adhesive film. In this way, portions of the lead frame panel and dice 212 that would make contact with the mold cavity during encapsulation instead make contact with the adhesive film. Thus, in one embodiment, during encapsulation, the surface of the protective layer 210 opposite the back surface of each die 212 is in contact with the adhesive film, which is turn in contact with the mold cavity. The adhesive film, too, generally aids in reducing mold compound intrusion over the back surfaces of the dice 212.

However, FAM systems are not always available or applicable to particular lead frame configurations. Hence, in another embodiment, an adhesive film may not be used whereby the protective layer 210 itself is in contact with the mold cavity. It should be noted that the use of protective layer 210 may obviate the need for FAM systems. Furthermore, the protective layer 210 can serve as a protective layer that aids in reducing chipping or other damage to the dice 212 and associated back surface metallic layers 208 as a result of contact with the mold cavity. A relatively soft protective layer 210 may also serve as a stress absorption layer. In particular, the protective layer 210 may absorb stresses during encapsulation of the die and thus help prevent the die from cracking during the encapsulation process.

During the encapsulation process, the mold cavity is pressed against the back surface of the die 212. Under sufficient pressure, protective layers 210 of certain materials may undergo deformation causing the protective layer 210 to shrink in thickness vertically and expand in length and width laterally such that portions of the protective layer 210 extend past the side edges and even below the back surface of the die 212. This may be undesirable in some embodiments and desirable in others. More particularly, if sufficient pressure is used during encapsulation, then after a die 212 is encapsulated with molding material and the protective layer 210 is removed, a shallow cavity may be present around the perimeter of the back surface of the die 212. In general, the thicker the protective layer 210 and the greater the molding pressure, the more the protective layer 210 will be deform and the deeper the cavity will be around the perimeter of the back surface of the die 212. Thus, it may be desirable in one embodiment to use a material to form the protective layer 210 that has a suitable elasticity so as to limit the amount of deformation of the protective layer 210 during encapsulation.

Although the protective layer 210 inhibits mold flashing, subsequent to encapsulation at 118, mold flash may be present on the protective layer 210. However, the protective layer 210 prevents molding compound from coming into contact with and adhering to the metallic layer 208. At 120, the protective layer 210 is removed by any suitable means. By way of example, protective layers formed of conventional solder mask materials may be removed upon exposure to a development solution such as an alkalide solution, sodium carbonate solution, potassium carbonate solution, or other basic solution, among others. In other embodiments, the protective layer 210 may be formed from a material that may be released from the metallic layer 208 upon exposure to radiation, such as UV radiation. Upon removal of the protective layer 210, the back surfaces of the dice 212 may be rinsed with water, and particularly deionized water. By way of example, a nozzle may be used to jet the water at a suitable pressure onto the metallic layers 208 on the back surfaces of the dice 212. The use of pressurized water may further aid in breaking up and removing any mold flash left over the back surfaces of the dice 212. However, the water rinse is an optional step that may or may not be used in specific embodiments.

Protective layers 210 formed of high temperature paints may be removed by one or more of a variety of readily available and inexpensive solvents including, but not limited to, isopropyl alcohol and acetone, among others. In one embodiment, the encapsulated dice 212 may be placed in a bath of a desired solvent whereby the solvent breaks down the protective layer 210.

In another embodiment, a more active means of removal may be desired. By way of example, the back surfaces of the dice 212 may be gently polished or buffed in addition to exposure to a suitable solvent (e.g., alcohol or acetone) to actively remove the protective layer 210 and mold flash. In one embodiment, a conventional buffer machine (generally used to polish dice) may be modified to include a suitable solvent injector used to inject a suitable solvent onto the back surfaces of the dice 212 while the buffer machine simultaneously polishes the back surfaces to actively remove the protective layer 210 and mold flash. Polishing is preferably done at the lead frame panel level; that is, prior to singulation of the encapsulated lead frame panel into individual IC packages. It should be noted that polishing must be performed carefully so as not to overly scratch or damage the metallic layer 208. However, it may be desirable in one embodiment to cause a limited amount of scratching in the metallic layer 208. More particularly, a limited amount of scratching may produce a rougher metallic layer surface that may facilitate solder plating the metallic layer 208. As described above, after exposure to the solvent, the back surfaces of the dice 212 may be rinsed with water, and particularly deionized water.

Protective layers 210 formed of emulsion material may be simply removed with water, and particularly deionized water. Preferably, a pressurized jet of water is used on the back surfaces of the dice 212 to break up and remove the protective layers 210 and any mold flash. As described above, the use of an industry standard water-based emulsion to form the protective layer 210 is particularly advantageous as the emulsion material works to soften and degrade any mold flash. Additionally, the water may be heated to elevated temperatures above room temperature to accelerate the removal process. As described above with respect to the removal of protective layers formed of paint, one or more of a variety of readily available and inexpensive solvents such as acetone may also be used alternatively or in conjunction with the water rinse.

It will be appreciated by those of skill in the art that the aforementioned methods of removal, as opposed to conventional methods such as laser deflashing, may be performed inline with typical packaging processes and generally with readily available equipment; that is, without transporting the dice to other locations where specialized equipment is required. Consequently, additional capital investment and increases in production times may be minimized. However, in some embodiments, methods such as laser deflashing may be used in conjunction with the aforementioned methods. If laser deflashing is used, the laser is preferably optimized in terms of power and wavelength so as not to damage the metallic layers 208, etch the molding compound outside the perimeter of the metallic layers, or contaminate the dice 212 with ions or otherwise damage the dice.

Upon removal of the protective layer 210, the metallic layer 208 is left exposed and uncovered by the molding compound. Subsequently, the molding compound may then be cured in a heated oven at 122. Curing is preferably done after removal of the protective layer 210. The reason for this ordering is that it is generally easier to remove the protective layer 210 prior to curing the molding compound because the curing process may dry and harden the protective layer. Curing the molding compound after removal of the protective layer 210 also serves to dry the encapsulated die if water was used to rinse the back surface of the die 212 and particularly the metallic layer 208.

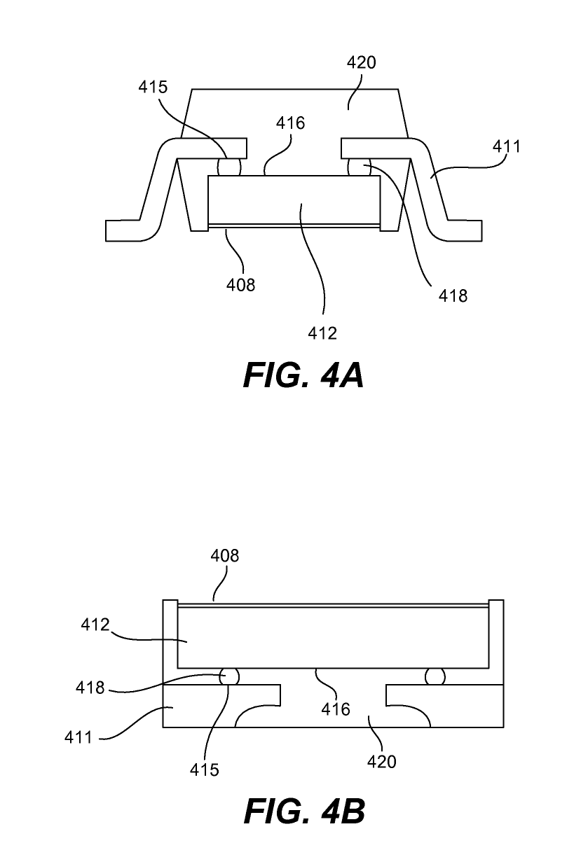

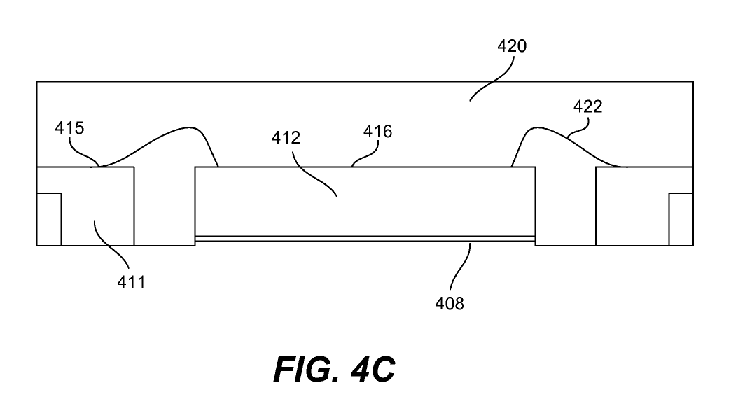

After curing the molding compound, the encapsulated lead frame panel 301 may then be singulated at 124 to yield a plurality of individual IC packages having exposed metallic layers on the back surfaces of the packaged dice. Examples of such packages include those illustrated in FIGS. 4A-4C. The encapsulated lead frame panel 301 may be singulated with any suitable means. By way of example, the lead frame panel 301 may be sawed to produce individual IC packages. Upon package singulation, the exposed IC packages may be attached to PCBs or other desired substrates. In many applications, the exposed metallic layers of the IC packages may be soldered directly to PCBs. It should be appreciated that the more surface area of the metallic layer that is exposed the stronger the resultant solder bond is between the package and the PCB, and the more heat transfer that is possible out of the die. Alternatively, in other embodiments it may be desirable to solder a heat sink onto the exposed metallic layer. Again, it is desirable to maximize the exposed surface area of the metallic layer in these embodiments as well.

FIGS. 4A-4B illustrate various exposed flip-chip-on-lead (FCOL) package configurations employing solder-bumped dice 412 in accordance with particular embodiments of the present invention. The packages illustrated in FIGS. 4A and 4B include a die 412 having an exposed metallic layer 408 on the back surface of the die. The die and portions of the leads 411 are encapsulated with molding compound 420 except for the exposed metallic layer 408. The die 412 is electrically and mechanically connected to the leads 411 via solder joints 418 that electrically and mechanically connect bond pads on the active surface 416 of the die to contact surfaces 415 on associated leads. FIG. 4A illustrates an exposed FCOL package in which the leads 411 are bent into a gull-wing formation to facilitate electrical connection to a PCB. In the configuration illustrated in FIG. 4A, the metallic layer 408 on the back surface of the die 412 may be directly soldered to a contact surface on a PCB. While FIG. 4B also illustrates an FCOL package, the metallic layer 408 in FIG. 4B is generally not intended to be soldered to a PCB.

In the embodiment illustrated in FIG. 4C, a die 412 not having solder bumps is positioned within a die attach area of a lead frame that does not include a die attach pad. In this embodiment, bond pads on the active surface 416 of the die are electrically connected to contact surfaces 415 on the leads 411 via bonding wires 422. Again, the die 412 and portions of the leads 411 are encapsulated with molding compound 420 while leaving metallic layer 408 on the back surface of the die exposed.

The foregoing description, for purposes of explanation, used specific nomenclature to provide a thorough understanding of the invention. However, it will be apparent to one skilled in the art that the specific details are not required in order to practice the invention. Thus, the foregoing descriptions of specific embodiments of the present invention are presented for purposes of illustration and description. They are not intended to be exhaustive or to limit the invention to the precise forms disclosed. It will be apparent to one of ordinary skill in the art that many modifications and variations are possible in view of the above teachings.

The embodiments were chosen and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents.

What is claimed is:

1. A method of packaging integrated circuit dice into exposed die packages, the method comprising:
depositing a metallic layer onto a back surface of an integrated circuit wafer, the wafer including a multiplicity of integrated circuit dice formed therein, each die having an active surface and a back surface, each active surface including a plurality of bond pads formed thereon, each back surface being substantially opposite the active surface, the back surfaces of the dice cooperating to form the back surface of the wafer, the metallic layer being deposited such that the metallic layer substantially covers the back surface of the wafer;
applying a protective layer over the metallic layer such that the protective layer substantially covers the metallic layer;
singulating the wafer into a multiplicity of individual integrated circuit dice after applying the protective layer over the metallic layer;
encapsulating a one of the singulated dice with a molding compound, whereby the protective layer on the die substantially prevents the molding compound from contacting the metallic layer on the die during the encapsulation process; and
removing the protective layer from the metallic layer on the encapsulated die thereby providing an individual IC package including a die having a metallic layer that is substantially entirely exposed on a back surface thereof.

2. A method as recited in claim 1, wherein the protective layer has a substantially uniform thickness in the range of approximately 25 to 50 μm.

3. A method as recited in claim 1, wherein the protective layer is formed from one of the group consisting of: a solder mask material, a high-temperature paint, or a water-based emulsion.

4. A method of packaging integrated circuit dice into exposed die packages, the method comprising:
providing an integrated circuit die, the die including a metallic layer deposited onto the back surface of the die such that the metallic layer substantially covers the back surface of the die, the die additionally including a protective layer applied over the metallic layer such that the protective layer substantially covers the metallic layer;
encapsulating the die with a molding compound, whereby the protective layer on the die substantially prevents the molding compound from contacting the metallic layer on the die during the encapsulation process; and
removing the protective layer from the metallic layer on the encapsulated die thereby providing an individual IC package including a die having a metallic layer that is substantially entirely exposed on a back surface thereof.

5. A method as recited in claim 4, wherein the protective layer has a substantially uniform thickness in the range of approximately 25 to 50 μm.

6. A method as recited in claim 4, further comprising soldering the metallic layer on the back surface of the die to a printed circuit board after the protective layer has been removed.

7. A method as recited in claim 4, further comprising electrically connecting the die to an associated device area of a lead frame prior to encapsulating the die.

8. A method as recited in claim 7, wherein each die includes a plurality of solder bumps formed on bond pads on the active surface of the die, and wherein electrically connecting the die to the lead frame comprises reflowing the solder bumps on the die.

9. A method as recited in claim 7, wherein electrically connecting the die to the lead frame comprises connecting bonds pads on the active surface of the die to contacts on the lead frame with bonding wires.

10. A method as recited in claim 7, wherein the lead frame is in the form of a strip and includes at least one two-dimensional array of device areas, adjacent device areas being connected with associated tie bars, each device area being suitable to receive an associated die, wherein the method comprises electrically connecting a die as recited in claim 4 to each of the device areas, and wherein the entire lead frame strip is encapsulated with molding compound substantially simultaneously, the method further comprising curing the molding compound around each encapsulated die after the associated protective layer has been removed from each die and singulating the encapsulated dice and lead frame after curing the molding compound to provide individual IC packages each having a die with an exposed metallic layer on a back surface thereof.

11. A method as recited in claim 4, wherein the protective layer is formed from one of the group consisting of: a solder mask material, a high-temperature paint, or a water-based emulsion.

12. A method of packaging integrated circuit dice into exposed die packages, the method comprising:
depositing a metallic layer onto a back surface of an integrated circuit wafer, the wafer including a multiplicity of integrated circuit dice formed therein, each die having an active surface and a back surface, each active surface including a plurality of bond pads formed thereon, each back surface being substantially opposite the active surface, the back surfaces of the dice cooperating to form the back surface of the wafer, the metallic layer being deposited such that the metallic layer substantially covers the back surface of the wafer; and
applying a protective layer of high temperature paint over the metallic layer such that the protective layer of high temperature paint substantially covers the metallic layer.

13. A method as recited in claim 12, wherein the protective layer of high temperature paint is applied with one selected from the group consisting of a spray on process, a roll on process or a screen printing process.

14. A method as recited in claim 12, further comprising:
singulating the wafer into a multiplicity of individual integrated circuit dice after applying the protective layer of high temperature paint over the metallic layer;
electrically connecting one of the singulated dice to a substrate;
encapsulating the electrically connected die with a molding compound, whereby the protective layer of high temperature paint on the die substantially prevents the molding compound from contacting the metallic layer on the die during the encapsulation process; and
removing the protective layer of high temperature paint from the metallic layer on the encapsulated die thereby providing an individual IC package including a die having a metallic layer that is substantially entirely exposed on a back surface thereof.

15. A method as recited in claim 14, wherein the protective layer of high temperature paint is removed by means of subjecting the protective layer of high temperature paint to one of an alcohol solution treatment or an acetone solution treatment.

16. A method of packaging integrated circuit dice into exposed die packages, the method comprising:
depositing a metallic layer onto a back surface of an integrated circuit wafer, the wafer including a multiplicity of integrated circuit dice formed therein, each die having an active surface and a back surface, each active surface including a plurality of bond pads formed thereon, each back surface being substantially opposite the active surface, the back surfaces of the dice cooperating to form the back surface of the wafer, the metallic layer being deposited such that the metallic layer substantially covers the back surface of the wafer; and
applying a protective layer of a water-based emulsion over the metallic layer such that the protective layer of water-based emulsion substantially covers the metallic layer.

17. A method as recited in claim 16, wherein the protective layer of water-based emulsion is applied with one selected from the group consisting of a spray on process, a roll on process, a spin coating process or a screen printing process.

18. A method as recited in claim 16, further comprising:
singulating the wafer into a multiplicity of individual integrated circuit dice after applying the protective layer of water-based emulsion over the metallic layer;
electrically connecting one of the singulated dice to a substrate;
encapsulating the electrically connected die with a molding compound, whereby the protective layer of water-based emulsion on the die substantially prevents the molding compound from contacting the metallic layer on the die during the encapsulation process; and
removing the protective layer of water-based emulsion from the metallic layer on the encapsulated die thereby providing an individual IC package including a die having a metallic layer that is substantially entirely exposed on a back surface thereof.

19. A method as recited in claim 18, wherein the protective layer of water-based emulsion is removed by means of subjecting the protective layer of water-based emulsion to one of a pressurized water rinse or an acetone solution.

20. An arrangement, comprising:
a wafer having a multiplicity of integrated circuit dice formed therein, each die having an active surface and a back surface, each active surface including a plurality of bond pads formed thereon, each back surface being substantially opposite the active surface, the back surfaces of the dice cooperating to form the back surface of the wafer;
a metallic layer deposited onto the back surface of the wafer, the metallic layer substantially covering the back surface of the wafer; and
a protective layer deposited onto the metallic layer, the protective layer substantially covering the metallic layer.

21. An arrangement as recited in claim 20, wherein the protective layer has a substantially uniform thickness in the range of approximately 25 to 50 μm.

22. An arrangement as recited in claim 20, wherein the protective layer is formed from one of the group consisting of: a solder mask material, a high-temperature paint, or a water-based emulsion.

23. An arrangement, comprising:
a lead frame panel including at least one two-dimensional array of device areas, adjacent device areas being connected with associated tie bars, each device area being suitable to receive an associated die; and
a plurality of dice, the dice being electrically connected to associated devices areas of the lead frame panel, each die including a metallic layer deposited onto the back surface of the die such that the metallic layer substantially covers the back surface of the die, each die additionally including a protective layer applied over the metallic layer such that the protective layer substantially covers the metallic layer.

24. An arrangement as recited in claim 23, wherein the protective layer has a substantially uniform thickness in the range of approximately 25 to 50 μm.

25. An arrangement as recited in claim 23, wherein the protective layer is formed from one of the group consisting of: a solder mask material, a high-temperature paint, or a water-based emulsion.
